(19) United States
(12) Patent Application Publication
(10) Pub. No.: US 2024/0101582 A1
(43) Pub. Date: Mar. 28, 2024

(54) INDENYL PRECURSORS

(71) Applicant: ENTEGRIS, INC., Billerica, MA (US)

(72) Inventors: Drew Michael Hood, Newtown, CT (US); Thomas M. Cameron, Newtown, CT (US)

(21) Appl. No.: 18/239,661

(22) Filed: Aug. 29, 2023

Related U.S. Application Data
(60) Provisional application No. 63/403,384, filed on Sep. 2, 2022.

(51) Int. Cl. C07F 7/00

(52) U.S. Cl. CPC C07F 7/00

(57) ABSTRACT

The compounds of the present disclosure have been developed and synthesized to generate compounds that provide improvements in film applications, such as HfOx, ZrOx, and TiOx film applications. The improvements to the compounds of the present disclosure include increased molecule stability at delivery temperature and deposition temperature, improvements related to precursor film impurity levels, molecule volatility, molecule melting point, and step coverage.

### FIELD

The present disclosure relates to the field of precursors, more specifically indenyl precursors such as indenyl substituted precursors.

### BACKGROUND

Thin films are used on semiconductor device structures.

### SUMMARY

The present disclosure relates to compounds of hafnium (Hf), zirconium (Zr), and titanium (Ti) indenyl (Ind) substituted precursors for deposition of group 4 containing thin films including HfOx, ZrOx, and TiOx. These thin films can be used in a variety of applications including semiconductor device structures. The compounds of the present disclosure have been developed and synthesized to generate compounds that provide improvements in film applications, such as HfOx, ZrOx, and TiOx film applications. The improvements to the compounds of the present disclosure include increased molecule stability at delivery temperature and deposition temperature, improvements related to precursor film impurity levels, molecule volatility, molecule melting point, and step coverage.

As tungsten is replaced by molybdenum in 3D-NAND, a blocking layer is needed to protect the aluminum oxide (Al₂O₃). Indenyl compounds of the present disclosure can be used as precursors with good stability and volatility. The indenyl compounds can be used for large scale production since indene can be used directly. Other compounds cannot be used directly. For example, cyclopentadiene (Cp) compounds may need to be first cracked.

In some embodiments, the compounds of the present disclosure can be used to grow group 4 metal oxide films. In some embodiments, the oxide films can be used in DRAM, NAND, gate, and hard mask applications. In some embodiments, the present disclosure relates to indenyl substituted group 4 compounds to be used as precursors for high-K metal oxide films.

Indenyl compounds of the present disclosure have good volatility, stability, and can be a good matchup for 3D-NAND applications. In some embodiments, precursors with good volatility are compatible with standard ALD equipment namely valves which can be approximately correlated to TGA data. For example, in some embodiments, if the TGA of a compound has a T50 less than 250° C., it is generally considered to be good. Precursors with good stability can be used with standard ALD equipment for long periods of time and can be approximately correlated to TGA data. For example, in some embodiments, if the TGA of a compound has residual mass of less than 10% it is generally considered to be good. Indenyl Hf compounds can be made in high purity from commodity chemicals. In some embodiments, high purity is defined as greater than 99% pure by NMR analysis.

In some aspects, the techniques described herein relate to a compound including:

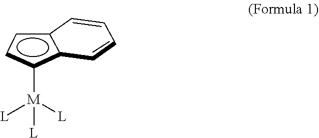

wherein M is titanium, zirconium, or hafnium, and wherein L is independently a C₁-C₁₅ alkyl, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H.

In some aspects, the techniques described herein relate to a compound, wherein M is hafnium.

In some aspects, the techniques described herein relate to a compound, wherein L is Cl, bis(2,2,2-trifluoroethyl)amido, 1,1,1,3,3,3-hexafluoro-2-propoxide, or 2,2,2-trifluoroethoxide.

In some aspects, the techniques described herein relate to a compound, wherein L consists of one cyclopentadienyl and two amido groups.

In some aspects, the techniques described herein relate to a compound, wherein the two amido groups include dimethylamdio, ethylmethylamido, or diethylamido.

In some aspects, the techniques described herein relate to a compound including:

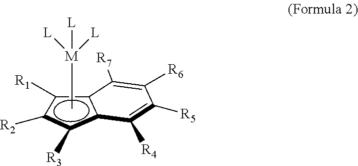

wherein M is titanium, zirconium, or hafnium, wherein L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ alkoxide containing at least one fluoro group, C₂-C₁₅ amide containing at least one fluoro group, F, Cl, Br, I, or H, and wherein R₁-R₇ are independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H. With at least one R₁-R₇ group containing a C₁-C₁₅ alkyl, C₁-C₁₅ ether, C₂-C₁₅ amine, C₁-C₁₅ fluoroether, C₁-C₁₅ fluoroalkyl, OH, F, Cl, Br, or I

In some aspects, the techniques described herein relate to a compound, wherein M is hafnium, and wherein L is dimethylamdio, ethylmethylamido, diethylamido, or bis(2,2,2-trifluoroethyl)amido.

In some aspects, the techniques described herein relate to a compound, wherein R₂ is methyl or ethyl, and wherein R₁, R₃, R₄, R₅, R₆, and R₇ are H.

In some aspects, the techniques described herein relate to a compound, wherein R₄ and R₇ are methyl, and wherein R₁, R₂, R₃, R₅, and R₆ are H.

In some aspects, the techniques described herein relate to a compound, wherein R₁ is CF₃, and wherein R₂-R₇ are H.

In some aspects, the techniques described herein relate to a compound, wherein R₁ is methyl or ethyl, and wherein R₂-R₇ are H.

In some aspects, the techniques described herein relate to a compound including:

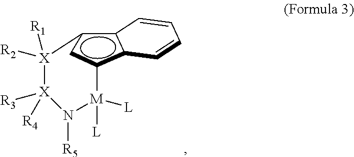

wherein M is titanium, zirconium, or hafnium, wherein L is independently L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H, wherein R₁-R₅ are independently a C₁-C₁₅ alkyl, C₁-C₁₅ fluoroalkyl, or H, and wherein X is independently C or Si.

In some aspects, the techniques described herein relate to a compound, wherein M is hafnium, and wherein L is dimethylamdio, ethylmethylamido, diethylamido, or bis(2,2,2-trifluoroethyl)amido.

In some aspects, the techniques described herein relate to a compound, wherein R₅ is methyl or ethyl, wherein R₁-R₄ are H, and wherein X is C.

In some aspects, the techniques described herein relate to a compound including:

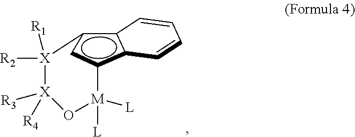

wherein M is titanium, zirconium, or hafnium, wherein L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H, wherein R₁-R₄ are independently a C₁-C₁₅ alkyl, C₁-C₁₅ fluoroalkyl, or H, and wherein X is independently C or Si

In some aspects, the techniques described herein relate to a compound, wherein M is hafnium, and wherein L is dimethylamdio, ethylmethylamido, diethylamido, or bis(2,2,2-trifluoroethyl)amido.

In some aspects, the techniques described herein relate to a compound, wherein R₁-R₃ are H, wherein R₄ is methyl or ethyl, and X is C.

In some aspects, the techniques described herein relate to a method for depositing a film, including: applying to a substrate a compound.

In some aspects, the techniques described herein relate to a method, wherein the compound is the compound of Formula (1).

In some aspects, the techniques described herein relate to a method, wherein the compound is the compound of Formula (2).

In some aspects, the techniques described herein relate to a method, wherein the compound is the compound of Formula (3).

In some aspects, the techniques described herein relate to a method, wherein the compound is the compound of Formula (4).

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1A displays a compound according to Formula 1, in accordance with some embodiments.

FIG. 1B displays a compound according to Formula 1, in accordance with some embodiments.

FIG. 1C displays a compound according to Formula 1, in accordance with some embodiments.

FIG. 2 displays a compound according to Formula 2, in accordance with some embodiments.

FIG. 3 displays a compound according to Formula 3, in accordance with some embodiments.

FIG. 4 displays a compound according to Formula 4, in accordance with some embodiments.

FIG. 5 displays compounds according to the present disclosure, in accordance with some embodiments.

FIG. 6 displays thermogravimetric analysis (TGA) of IndHf(Cl)₃, in accordance with some embodiments.

FIG. 7 displays TGA of 2-MeIndHf(NMe₂)₃, in accordance with some embodiments.

FIG. 8 displays a ¹H-NMR spectrum of 2-MeIndHf(NMe₂)₃, in accordance with some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or
any combination(s) thereof.

As used herein “embedded” means that a first material is distributed throughout a second material.

The present disclosure relates to indenyl hafnium, zirconium, and titanium precursors for the deposition of HfOx, ZrOx, and TiOx thin films. These thin films can be used in a variety of applications including semiconductor device structures. For example, the compounds of the present disclosure have been developed and synthesized to generate compounds that provide improvements in film applications, such as HfOx, ZrOx, and TiOx film applications. The improvements to the compounds of the present disclosure include increased molecule stability at delivery temperature and deposition temperature, improvements related to precursor film impurity levels, molecule volatility, molecule melting point, and step coverage.

As tungsten is replaced by molybdenum in 3D-NAND, a blocking layer is needed to protect the aluminum oxide (Al₂O₃). Indenyl compounds, such as indenyl Hf compounds, can be used as precursors with good stability and volatility. The indenyl compounds, such as indenyl Hf compounds, can be used for large scale production since indene can be used directly. Other compounds cannot be used directly. For example, cyclopentadiene (Cp) compounds may need to be first cracked. In addition, other compounds can form potentially explosive solutions.

In some embodiments, the compounds of the present disclosure can be used to grow group 4 metal oxide films. In some embodiments, the oxide films can be used in DRAM, NAND, gate, and hard mask applications. In some embodiments, the present disclosure relates to indenyl substituted group 4 compounds to be used as precursors for high-K metal oxide films.

Indenyl Hf compounds have good volatility, stability, and can be a good matchup for 3D-NAND applications. Indenyl Hf compounds can be made in high purity from commodity chemicals.

In some embodiments, the compound of the present disclosure comprises a compound with the following formula:

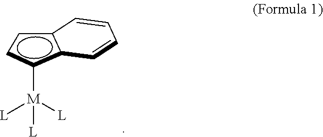

In some embodiments, for Formula 1, M is titanium, zirconium, or hafnium. In some embodiments, for Formula 1, L is independently a C₁-C₁₅ alkyl, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H.

In some embodiments, for Formula 1, M is hafnium.

In some embodiments, for Formula 1, L is Cl (chlorine), bis(2,2,2-trifluoroethyl)amido, 1,1,1,3,3,3-hexafluoro-2-propoxide, or 2,2,2-trifluoroethoxide.

In some embodiments, for Formula 1, L consists of one cyclopentadienyl and two amido groups. In some embodiments, the two amido groups comprise dimethylamdio, ethylmethylamido, or diethylamido.

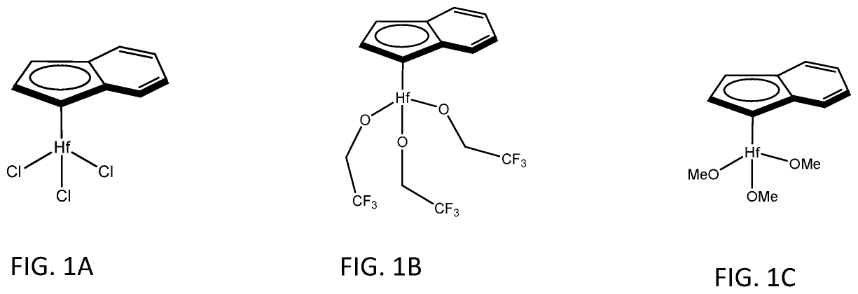

FIG. 1A displays a compound according to Formula 1, in accordance with some embodiments. In some embodiments, FIG. 1A displays the compound, IndHf(Cl)₃, for Formula 1 when M is Hf and L is Cl.

In some embodiments, for Formula 1, M is Hf and L is bis(2,2,2-trifluoroethyl)amido.

In some embodiments, for Formula 1, M is Hf and L is 1,1,1,3,3,3-hexafluoro-2-propoxide or 2,2,2-trifluoroethoxide. FIG. 1B displays a compound according to Formula 1, in accordance with some embodiments. FIG. 1B displays the compound when M is Hf and L is 2,2,2-trifluoroethoxide.

In some embodiments, for Formula 1, M is Hf and L is OMe. FIG. 1C displays the compound for Formula 1 when M is Hf and L is OMe.

In some embodiments, M is Hf and L consists of one cyclopentadienyl and two amido groups, specifically dimethylamdio, ethylmethylamido, or diethylamido.

In some embodiments, the compound of the present disclosure comprises a compound with the following formula:

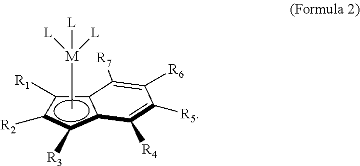

In some embodiments, M is titanium, zirconium, or hafnium.

In some embodiments, L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ alkoxide containing at least one fluoro group, C₂-C₁₅ amide containing at least one fluoro group, F, Cl, Br, I, or H,

In some embodiments, R₁-R₇ are independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H. With at least one R₁-R₇ group containing a C₁-C₁₅ alkyl, C₁-C₁₅ ether, C₂-C₁₅ amine, C₁-C₁₅ fluoroether, C₁-C₁₅ fluoroalkyl, OH, F, Cl, Br, or I.

In some embodiments, M is hafnium, and L is dimethylamdio, ethylmethylamido, diethylamido, or bis(2,2,2-trifluoroethyl)amido.

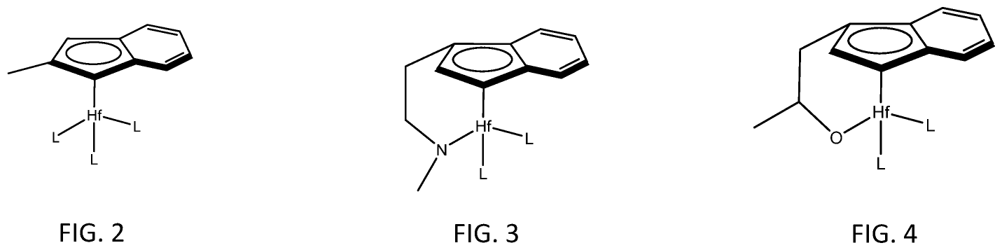

In some embodiments, R₂ is methyl or ethyl, and R₁, R₃, R₄, R₅, R₆, and R₇ are H. FIG. 2 displays a compound according to Formula 2, in accordance with some embodiments. FIG. 2 displays the compound for Formula 2 when M is Hf; R₂ is methyl; and R₁, R₃, R₄, R₅, R₆, and R₇ are H.

In some embodiments, R₄ and R₇ are methyl, and R₁, R₂, R₃, R₅, and R₆ are H.

In some embodiments, R₁ is CF₃, and R₂-R₇ are H.

In some embodiments, R₁ is methyl or ethyl, and R₂-R₇ are H.

In some embodiments, M is hafnium; L is dimethylamdio, ethylmethylamido, diethylamido, or bis(2,2,2-trifluoroethyl)amido; R₂ is methyl or ethyl; and R₁, R₃, R₄, R₅, R₆, and R₇ are H.

In some embodiments, M is hafnium; L is dimethylamdio, ethylmethylamido, diethylamido, or bis(2,2,2-trifluoroethyl)amido; R₄ and R₇ are methyl; and R₁, R₂, R₃, R₅, and R₆ are H.

In some embodiments, M is hafnium; L is dimethylamdio, ethylmethylamido, diethylamido, or bis(2,2,2-trifluoroethyl)amido; R₁ is CF₃; and R₂-R₇ are H.

In some embodiments, M is hafnium; L is dimethylamdio, ethylmethylamido, diethylamido, or bis(2,2,2-trifluoroethyl)amido; R₁ is methyl or ethyl; and R₂-R₇ are H.

In some embodiments, the compound of the present disclosure comprises a compound with the following formula:

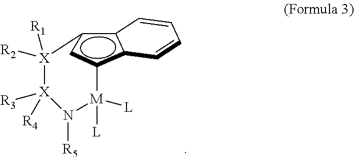

In some embodiments, M is titanium, zirconium, or hafnium.

In some embodiments, L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H.

In some embodiments, R₁-R₅ are independently a C₁-C₁₅ alkyl, C₁-C₁₅ fluoroalkyl, or H.

In some embodiments, X is independently C or Si.

In some embodiments, M is hafnium, and L is dimethylamdio, ethylmethylamido, diethylamido, or bis(2,2,2-trifluoroethyl)amido.

In some embodiments, R₅ is methyl or ethyl, R₁-R₄ are H, and X is C. FIG. 3 displays a compound according to Formula 3, in accordance with some embodiments. FIG. 3 displays the compound for Formula 3 when M is Hf; R₅ is methyl; R₁-R₄ are H; and X is C.

In some embodiments, M is hafnium; L is dimethylamdio, ethylmethylamido, diethylamido, or bis(2,2,2-trifluoroethyl)amido; R₅ is methyl or ethyl; R₁-R₄ are H; and X is C.

In some embodiments, the compound of the present disclosure comprises a compound with the following formula:

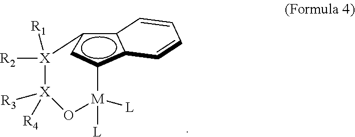

In some embodiments, M is titanium, zirconium, or hafnium,

In some embodiments, L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H,

In some embodiments, R₁-R₄ are independently a C₁-C₁₅ alkyl, C₁-C₁₅ fluoroalkyl, or H, and

In some embodiments, X is independently C or Si.

In some embodiments, M is hafnium, and L is dimethylamdio, ethylmethylamido, diethylamido, or bis(2,2,2-trifluoroethyl)amido.

In some embodiments, R₁-R₃ are H; R₄ is methyl or ethyl; and X is C. FIG. 4 displays a compound according to Formula 4, in accordance with some embodiments. FIG. 4 displays the compound for Formula 4 when M is Hf; R₁-R₃ are H; R₄ is methyl; and X is C.

In some embodiments, M is hafnium; L is dimethylamdio, ethylmethylamido, diethylamido, or bis(2,2,2-trifluoroethyl)amido; R₁-R₃ are H; R₄ is methyl or ethyl; and X is C.

In some embodiments, the method of the present disclosure relates to depositing a film, including applying to a substrate a compound as described herein. In some embodiments, the compound is a compound with Formula 1 of the present disclosure. In some embodiments, the compound is a compound with Formula 2 of the present disclosure. In some embodiments, the compound is a compound with Formula 3 of the present disclosure. In some embodiments, the compound is a compound with Formula 4 of the present disclosure.

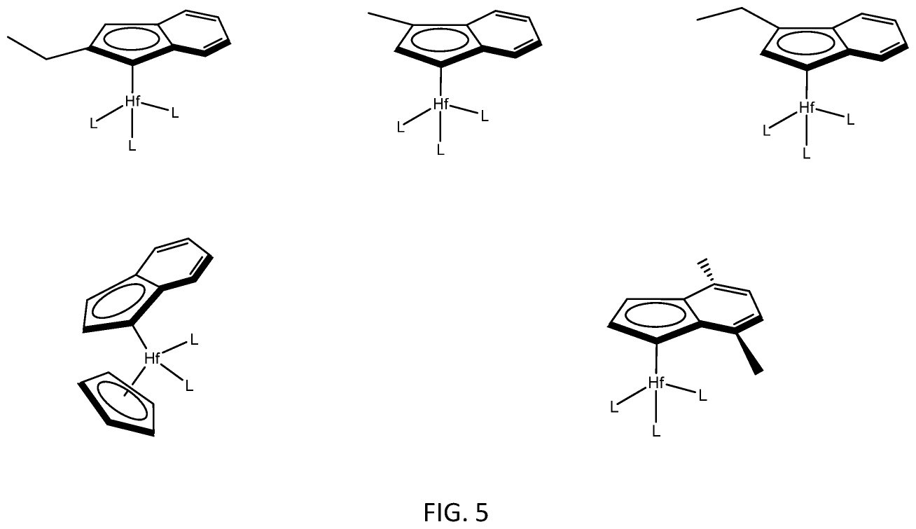

FIG. 5 displays compounds according to the present disclosure, in accordance with some embodiments. For FIG. 5, the metal is Hafnium. For the compounds shown in FIG. 5, each L can independently be NMe₂, NEtMe, NEt₂, OMe, OEt, Oi-Pr, Ot-Bu, Cl, Br, I, Cp, Me, H, Amide, Alkoxide, Carboxylate, Fluorinated Alkoxide, Fluorinated Amide, Substituted Cp, Amidinate, Guanidinate, β-diketonate, β-ketoiminate, or β-diketiminate.

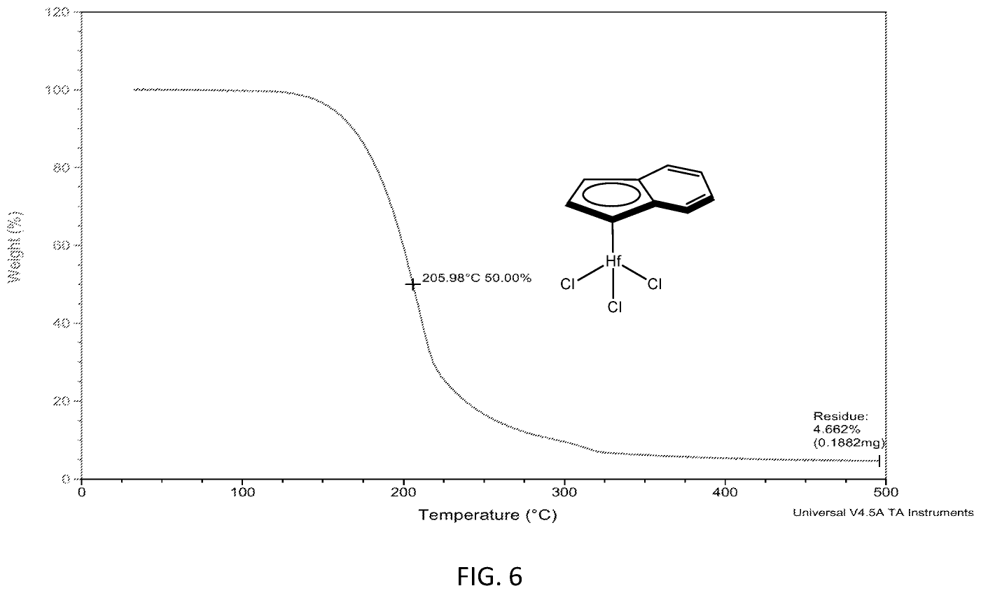

FIG. 6 displays thermogravimetric analysis TGA of IndHf(Cl)₃, in accordance with some embodiments. FIG. 6 displays TGA of the compound of FIG. 1A, IndHf(Cl)₃. The temperature when there is 50% residual mass is 205.98 degrees Celsius. The residue is 4.662% (0.1882 mg).

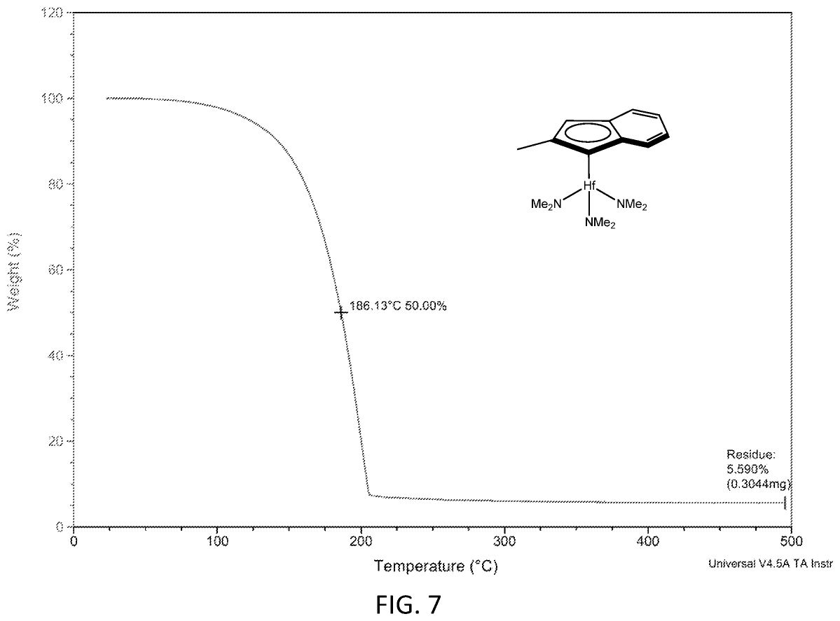

FIG. 7 displays TGA of 2-MeIndHf(NMe₂)₃, in accordance with some embodiments. For 2-MeIndHf(NMe₂)₃, the temperature when there is 50% residual mass is 200.98 degrees Celsius. The residue is 7.437% (0.6868 mg).

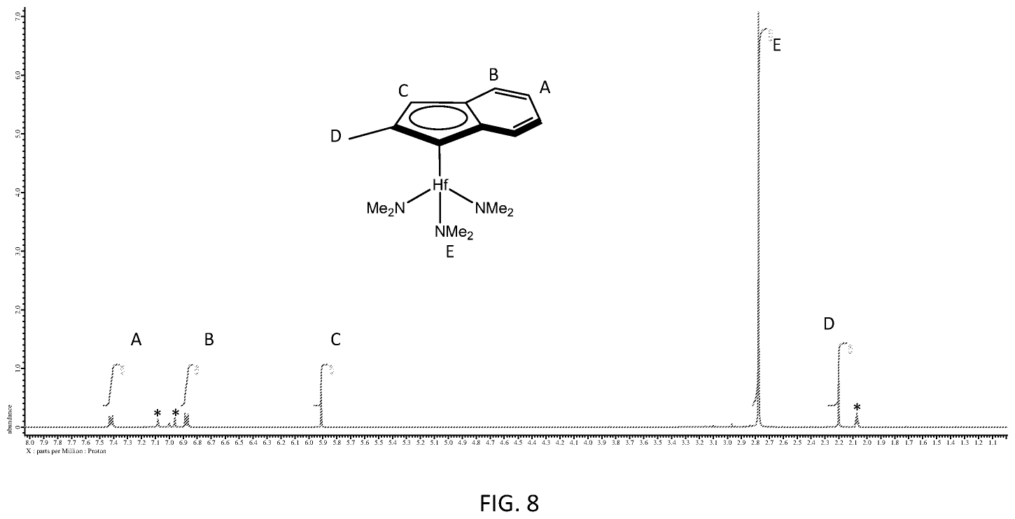

FIG. 8 displays a NMR of 2-MeIndHf(NMe₂)₃, in accordance with some embodiments.

### ASPECTS

Various Aspects are described below. It is to be understood that any one or more of the features recited in the following Aspect(s) can be combined with any one or more other Aspect(s).

Aspect 1. A compound comprising:

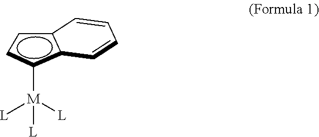

wherein M is titanium, zirconium, or hafnium, and wherein L is independently a C₁-C₁₅ alkyl, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H.

Aspect 2. The compound of Aspect 1, wherein M is hafnium.

Aspect 3. The compound of Aspect 1 or Aspect 2, wherein L is Cl, bis(2,2,2-trifluoroethyl)amido, 1,1,1,3,3,3-hexafluoro-2-propoxide, or 2,2,2-trifluoroethoxide.

Aspect 4. The compound of Aspect 1 or Aspect 2, wherein L consists of one cyclopentadienyl and two amido groups.

Aspect 5. The compound of Aspect 4, wherein the two amido groups comprise dimethylamdio, ethylmethylamido, or diethylamido.

Aspect 6. A compound comprising:

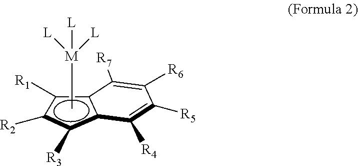

wherein M is titanium, zirconium, or hafnium, wherein L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ alkoxide containing at least one fluoro group, C₂-C₁₅ amide containing at least one fluoro group, F, Cl, Br, I, or H, and wherein R₁-R₇ are independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H. With at least one R₁-R₇ group containing a C₁-C₁₅ alkyl, C₁-C₁₅ ether, C₂-C₁₅ amine, C₁-C₁₅ fluoroether, C₁-C₁₅ fluoroalkyl, OH, F, Cl, Br, or I.

Aspect 7. The compound of Aspect 6, wherein M is hafnium, and wherein L is dimethylamdio, ethylmethylamido, diethylamido, or bis(2,2,2-trifluoroethyl)amido.

Aspect 8. The compound of Aspect 6 or Aspect 7, wherein R₂ is methyl or ethyl, and wherein R₁, R₃, R₄, R₅, R₆, and R₇ are H.

Aspect 9. The compound of Aspect 6 or Aspect 7, wherein R₄ and R₇ are methyl, and wherein R₁, R₂, R₃, R₅, and R₆ are H.

Aspect 10. The compound of Aspect 6 or Aspect 7, wherein R₁ is CF₃, and wherein R₂-R₇ are H.

Aspect 11. The compound of Aspect 6 or Aspect 7, wherein R₁ is methyl or ethyl, and wherein R₂-R₇ are H.

Aspect 12. A compound comprising:

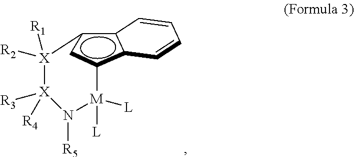

wherein M is titanium, zirconium, or hafnium, wherein L is independently L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H, wherein R₁-R₅ are independently a C₁-C₁₅ alkyl, C₁-C₁₅ fluoroalkyl, or H, and wherein X is independently C or Si.

Aspect 13. The compound of Aspect 12, wherein M is hafnium, and wherein L is dimethylamdio, ethylmethylamido, diethylamido, or bis(2,2,2-trifluoroethyl)amido.

Aspect 14. The compound of Aspect 12 or Aspect 13, wherein R₅ is methyl or ethyl, wherein R₁-R₄ are H, and wherein X is C.

Aspect 15. A compound comprising:

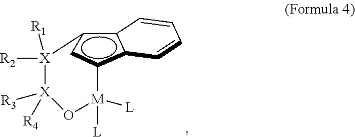

wherein M is titanium, zirconium, or hafnium, wherein L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H, wherein R₁-R₄ are independently a C₁-C₁₅ alkyl, C₁-C₁₅ fluoroalkyl, or H, and wherein X is independently C or Si.

Aspect 16. The compound of Aspect 15, wherein M is hafnium, and wherein L is dimethylamdio, ethylmethylamido, diethylamido, or bis(2,2,2-trifluoroethyl)amido.

Aspect 17. The compound of Aspect 15 or Aspect 16, wherein R₁-R₃ are H, wherein R₄ is methyl or ethyl, and X is C.

Aspect 18. A method for depositing a film, comprising: applying to a substrate a compound of Aspects 1-17.

Aspect 19. The method of Aspect 18, wherein the compound is the compound of Aspect 1.

Aspect 20. The method of Aspect 18, wherein the compound is the compound of Aspect 6.

Aspect 21. The method of Aspect 18, wherein the compound is the compound of Aspect 12.

Aspect 22. The method of Aspect 18, wherein the compound is the compound of Aspect 15.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A compound comprising: 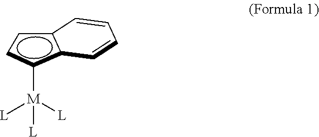
wherein M is titanium, zirconium, or hafnium, and
wherein L is independently a C₁-C₁₅ alkyl, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H.

2. The compound of claim 1,
wherein M is hafnium.

3. The compound of claim 1,
wherein L is Cl, bis(2,2,2-trifluoroethyl)amido, 1,1,1,3,3,3-hexafluoro-2-propoxide, or 2,2,2-trifluoroethoxide.

4. The compound of claim 1,
wherein L consists of one cyclopentadienyl and two amido groups.

5. The compound of claim 4,
wherein the two amido groups comprise dimethylamdio, ethylmethylamido, or diethylamido.

6. A compound comprising: 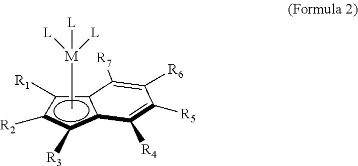
wherein M is titanium, zirconium, or hafnium,
wherein L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ alkoxide containing at least one fluoro group, C₂-C₁₅ amide containing at least one fluoro group, F, Cl, Br, I, or H, and
wherein R₁-R₇ are independently a C₁-C₁₅ alkyl, C₁-C₁₅ ether, C₂-C₁₅ amine, C₁-C₁₅ fluoroether, C₁-C₁₅ fluoroalkyl, OH, F, Cl, Br, I, or H. With at least one R₁-R₇ group containing a C₁-C₁₅ alkyl, C₁-C₁₅ ether, C₂-C₁₅ amine, C₁-C₁₅ fluoroether, C₁-C₁₅ fluoroalkyl, OH, F, Cl, Br, or I.

7. The compound of claim 6,
wherein M is hafnium, and
wherein L is dimethylamdio, ethylmethylamido, diethylamido, or bis(2,2,2-trifluoroethyl)amido.

8. The compound of claim 6,
wherein R₂ is methyl or ethyl, and
wherein R₁, R₃, R₄, R₅, R₆, and R₇ are H.

9. The compound of claim 6,
wherein R₄ and R₇ are methyl, and
wherein R₁, R₂, R₃, R₅, and R₆ are H.

10. The compound of claim 6,
wherein R₁ is CF₃, and
wherein R₂-R₇ are H.

11. The compound of claim 6,
wherein R₁ is methyl or ethyl, and
wherein R₂-R₇ are H.

12. A compound comprising: 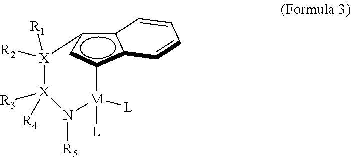
wherein M is titanium, zirconium, or hafnium,
wherein L is independently L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H,
wherein R₁-R₅ are independently a C₁-C₁₅ alkyl, C₁-C₁₅ fluoroalkyl, or H, and
wherein X is independently C or Si.

13. The compound of claim 12,
wherein M is hafnium, and
wherein L is dimethylamdio, ethylmethylamido, diethylamido, or bis(2,2,2-trifluoroethyl)amido.

14. The compound of claim 12,
wherein R₅ is methyl or ethyl,
wherein R₁-R₄ are H, and
wherein X is C.

15. A compound comprising: 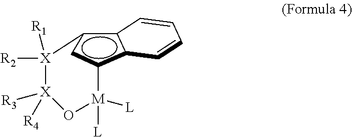
wherein M is titanium, zirconium, or hafnium,
wherein L is independently a C₁-C₁₅ alkyl, C₂-C₁₅ amide, C₁-C₁₅ alkoxide, C₁-C₁₅ carboxylate, cyclopentadienyl, methylcyclopentadienyl, ethylcyclopentadienyl, isopropylcyclopentadienyl, pentamethylcyclopentadienyl, C₅-C₁₅ amidinate, C₅-C₁₅ guanidinate, C₅-C₁₅ β-diketonate, C₅-C₁₅ β-ketoiminate, C₅-C₁₅ β-diketiminate, C₁-C₁₅ fluoroalkyl, C₁-C₁₅ alkoxide containing at least one fluoro group, C₂-C₁₅ amide containing at least one fluoro group, F, Cl, Br, I, or H,
wherein R₁-R₄ are independently a C₁-C₁₅ alkyl, C₁-C₁₅ fluoroalkyl, or H, and
wherein X is independently C or Si.

16. The compound of claim 15,
wherein M is hafnium, and
wherein L is dimethylamdio, ethylmethylamido, diethylamido, or bis(2,2,2-trifluoroethyl)amido.

17. The compound of claim 15,
wherein R₁-R₃ are H,
wherein R₄ is methyl or ethyl, and
X is C.
